(19) United States
(12) Patent Application Publication
(10) Pub. No.: US 2021/0405463 A1
(43) Pub. Date: Dec. 30, 2021

(54) DISPLAY SUBSTRATE, MANUFACTURING METHOD THEREOF, AND DISPLAY APPARATUS

(71) Applicants: HEFEI BOE DISPLAY TECHNOLOGY CO., LTD., Hefei, Anhui (CN); BOE TECHNOLOGY GROUP CO., LTD., Beijing (CN)

(72) Inventors: Zhonghou Wu, Beijing (CN); Chunxu Zhang, Beijing (CN); Ke Dai, Beijing (CN); Peng Jiang, Beijing (CN); Jingang Liu, Beijing (CN); Lihui Han, Beijing (CN); Yuntian Zhang, Beijing (CN)

(73) Assignees: HEFEI BOE DISPLAY TECHNOLOGY CO., LTD., Hefei, Anhui (CN); BOE TECHNOLOGY GROUP CO., LTD., Beijing (CN)

(21) Appl. No.: 16/769,083

(22) PCT Filed: Dec. 23, 2019
(86) PCT No.: PCT/CN2019/127411

§ 371 Date: Jun. 2, 2020

(30) Foreign Application Priority Data
Jun. 13, 2019 (CN) 201910510106.9

(51) Int. Cl. G02F 1/1343; H01L 27/12; G02F 1/1333; G02F 1/1362; G02F 1/1368

(52) U.S. Cl. CPC G02F 1/134309; H01L 27/124; H01L 27/1259; G02F 1/13439; G02F 1/136295; G02F 1/1368; G02F 1/133345

(57) ABSTRACT

The disclosure relates to a display substrate. The display substrate may include a semiconductor pattern and a first conductive pattern stacked on a base substrate, and a second conductive pattern electrically connected to the first conductive pattern. A first orthographic projection of the first conductive pattern on the base substrate may fall within a second orthographic projection of the semiconductor pattern on the base substrate, and a distance between the second orthographic projection and a fourth orthographic projection of a display electrode of the display substrate on the base substrate ma be greater than a distance between a third orthographic projection of the second conductive pattern on the base substrate and the fourth orthographic projection.

### CROSS-REFERENCE TO RELATED APPLICATIONS

This application claims benefit of the filing date of Chinese Patent Application No. 201910510106.9 filed on Jun. 13, 2019, the disclosure of which is hereby incorporated in its entirety by reference.

### TECHNICAL FIELD

The present disclosure relates to the field of display technology, and in particular to a display substrate, a manufacturing method thereof, and a display apparatus.

### BACKGROUND

In a conventional liquid crystal display apparatus, a semi-transmissive mask is used to form a pattern of a semiconductor layer and a pattern of a source/drain metal layer. Due to the limitation of the etching process, after the pattern of the semiconductor layer and the pattern of the source and drain metal layers are formed, the pattern of the semiconductor layer may exceed the boundary of the pattern of the source and drain metal layers. For example, a semiconductor pattern having the same direction as the extension of the data line remains under the data line, and the data line cannot completely cover the semiconductor pattern. At the same time the backlight of the liquid crystal display apparatus adjusts the brightness of the backlight by adjusting the duty ratio of the driving signal, so that the backlight has a period of light emission and no light emission. When the backlight emits light, the semiconductor pattern under the data line is affected by the illumination and appears as a conductor. When the backlight is not illuminated, the semiconductor pattern still exhibits semiconductor performance.

When the backlight is not illuminated, the lateral capacitance between the data line and the common electrode or the pixel electrode is determined by the distance between the data line and the common electrode or the pixel electrode. When the backlight emits light, since the semiconductor pattern appears as a conductor, and the distance between the semiconductor pattern and the common electrode or the pixel electrode is smaller than the distance between the data line and the common electrode or the pixel electrode, the lateral capacitance between the data line and the common electrode or the pixel electrode is determined by the distance between the semiconductor pattern and the common electrode or the pixel electrode. In this way, in the cases where the backlight emits light or does not emit light, the lateral capacitance between the data line and the common electrode or the pixel electrode changes, thereby affecting the load on the data line, causing a difference in pixel Charging, and resulting in a poor display of the display apparatus.

### BRIEF SUMMARY

An embodiment of the present disclosure provides a display substrate. The display substrate may include a semiconductor pattern and a first conductive pattern stacked on a base substrate, and a second conductive pattern electrically connected to the. first conductive pattern. A first orthographic projection of the first conductive pattern on the base substrate may fall within a second orthographic projection of the semiconductor pattern on the base substrate and a distance between the second orthographic projection and a fourth orthographic projection of a display electrode of the display substrate on the base substrate may be greater than a distance between a third orthographic projection of the second conductive pattern on the base substrate and the fourth orthographic projection.

Optionally, the second orthographic projection falls within the third orthographic projection.

Optionally, the first conductive pattern is connected in parallel with the second conductive pattern.

Optionally, the display electrode comprises a first display electrode and a second display electrode, and the second conductive pattern is disposed in a same layer and made of a same material as the first display electrode of the display substrate.

Optionally, the second conductive pattern is separated from the first conductive pattern by an insulating layer, the display substrate further comprises a conductive connection portion connecting the second conductive pattern and the first conductive pattern, and the conductive connection portion is made of a same material as the second display electrode of the display substrate.

Optionally, the first display electrode is one of a common electrode or a pixel electrode, and the second display electrode is the other one of the common electrode or the pixel electrode.

Optionally, the first conductive pattern is a data line of the display substrate.

Optionally, the second conductive pattern is disposed in a same layer and made of a same material as a gate line of the display substrate and is insulated from the gate line.

Optionally, the second conductive pattern is between the semiconductor pattern and the base substrate, and the second conductive pattern is made of an opaque metal.

Optionally, the first conductive pattern is a source or a drain of a thin film transistor on the display substrate.

Optionally, the semiconductor pattern is under the source or the drain of the thin film transistor, and the source or the drain does not completely cover the semiconductor pattern.

One embodiment of the present disclosure is a display apparatus comprising the display substrate according to one embodiment of the present disclosure.

One embodiment of the present disclosure is a manufacturing method of a display substrate, comprising forming a semiconductor pattern and a first conductive pattern stacked on a base substrate, and forming a second conductive pattern electrically connected to the first conductive pattern, wherein a first orthographic projection of the first conductive pattern on the base substrate falls within a second orthographic projection of the semiconductor pattern on the base substrate, a distance between the second orthographic projection and a fourth orthographic projection of a display electrode of the display substrate on the base substrate is greater than a distance between a third orthographic projection of the second conductive pattern on the base substrate and the fourth orthographic projection.

Optionally the first conductive pattern is connected in parallel with the second conductive pattern.

Optionally, the display electrode comprises a first display electrode and a second display electrode, and forming the second conductive pattern comprising forming the second conductive pattern and the first display electrode of the display substrate by one patterning process.

The second conductive pat and the first conductive pattern are separated by an insulating layer, and the manufacturing method further comprising forming a conductive connection portion connecting the second conductive pattern with the first conductive pattern and the second display electrode of the display substrate by one patterning process.

Optionally, the first display electrode is one of a common electrode or a pixel electrode, and the second display electrode is the other one of the common electrode or the pixel electrode.

Optionally, the first conductive pattern is a data line of the display substrate, and forming the second conductive pattern comprising forming the second conductive pattern and a gate line of the display substrate by one patterning process.

Optionally, the second conductive pattern is between the semiconductor pattern and the base substrate, and the second conductive pattern is made of an opaque metal.

Optionally, the first conductive pattern is a source or a drain of a thin film transistor on the display substrate.

### BRIEF DESCRIPTION OF THE DRAWINGS

FIG. 1 is a schematic plan view of a display substrate according to an embodiment of the disclosure;

FIG. 2 is a schematic cross-sectional view of FIG. 1 in the AA direction;

FIG. 3 is a schematic plan view of a display substrate according to another embodiment of the disclosure:

FIG. 4 is a schematic cross-sectional view of FIG. 3 in the AA direction;

FIG. 5 is a schematic plan view of a display substrate according to an embodiment of the disclosure;

FIG. 6 is a schematic plan view of a display substrate according to an embodiment of the disclosure.

### DETAILED DESCRIPTION

In order to make the technical problems, technical solutions and advantages to be solved by the embodiments of the present disclosure more clear, the detailed description will be made below in conjunction with the accompanying drawings and specific embodiments.

In the conventional liquid crystal display apparatus, after the pattern of the semiconductor layer and the pattern of the source and drain metal layers are formed, the pattern of the semiconductor layer may exceed the boundary of the pattern of the source and drain metal layers. At the same time, the backlight of the liquid crystal display apparatus adjusts the brightness of the backlight by adjusting the duty ratio of the driving signal, so that the backlight has a period of light emission and no light emission. Since the conductivity of the semiconductor pattern is affected by the illumination, the lateral capacitance between the data line and the common electrode or the pixel electrode changes when the backlight emits light or does not emit light. In turn, the load on the data line is affected, resulting in a difference in pixel charging and display failure of the display apparatus. The display failure is that alternation of horizontal light stripes and dark strips in the pure green picture fall like water, named “Water Fall”.

One embodiment of the present disclosure provides a display substrate, a manufacturing method thereof, and a display apparatus, which can improve the display effect of the display apparatus.

Some embodiments of the present disclosure provide a display substrate including a semiconductor pattern and a first conductive pattern stacked on a base substrate. A first orthographic projection of the first conductive pattern on the base substrate falls within a second orthographic projection of the semiconductor pattern on the base substrate. The display substrate further comprises a second conductive pattern electrically connected to the first conductive pattern, a distance between the second orthographic projection and a fourth orthographic projection of the display electrode of the display substrate on the substrate is greater than a distance between the third orthographic, projection of the second conductive pattern on the base substrate and the fourth orthographic projection.

Wherein the distance between the second orthographic projection and the fourth orthographic projection is the shortest distance between the boundary of the second orthographic projection near the fourth orthographic projection and the boundary of the fourth orthographic projection near the second orthographic projection, and the distance between the third orthographic projection and the fourth orthographic projection is the shortest distance between the boundary of the third orthographic projection near the fourth orthographic projection and the boundary of the fourth orthographic projection near the third orthographic projection.

In this embodiment, the display substrate includes a second conductive pattern electrically connected to the first conductive pattern, and the distance between the second orthographic projection and the fourth orthographic projection of the display electrode of the display substrate on the substrate is greater than the distance between the third orthographic projection of the second conductive pattern on the base substrate and the fourth orthographic. projection. Thus, when the display substrate is in operation, the lateral capacitance between the first conductive pattern and the display electrode is determined by the distance between the second conductive pattern and the display electrode, rather than the distance between the semiconductor pattern and the display electrode. Since the second conductive pattern is always a :conductor, the lateral capacitance between the first conductive pattern and the display electrode does not change in the case where the backlight emits light or does not emit light. Therefore, the load on the first conductive pattern is not affected, the difference in pixel charging is not generated, and the display apparatus is prevented from being poorly displayed. In addition, the first conductive pattern can be connected to the second conductive pattern through a plurality of connection points. Thus, the first conductive pattern may he connected in parallel with the second conductive pattern, and the resistance of the first conductive pattern can also be reduced.

In one embodiment, the second orthographic projection falls within the third orthographic projection such that in the region where the semiconductor pattern is present, the orthographic projection of the semiconductor pattern on the base substrate falls into the orthographic projection of the second conductive pattern on the base substrate, and the distance between the second conductive pattern and the display electrode of the display substrate is smaller than the distance between the semiconductor pattern and the display electrode. Thus, when the display substrate is in operation, the lateral capacitance between the first conductive pattern and the display electrode is determined by the distance between the second conductive pattern arid the display electrode, rather than the distance between the semiconductor pattern and the display electrode. Thus, the lateral capacitance between the first conductive pattern and the display electrode does not change in the cases where the backlight emits light or does not emit light. Therefore, the load on the first conductive pattern is not affected, the difference in pixel charging is not generated, and the display apparatus is prevented from being poorly displayed. The distance between the first conductive pattern and the display electrode is the distance between the two in the horizontal direction, that is, the distance between the orthographic projections of the two on the substrate. For example, the distance between the second conductive pattern and the display electrode of the display substrate is the distance between the third orthographic projection and the orthographic projection of the display electrode on the base substrate, the distance between the semiconductor pattern and the display electrode is the distance between the second orthographic projection and the orthographic. projection of the display electrode on the base substrate, and the distance between the orthographic projections is the shortest distance between the contours of the orthographic projection.

Wherein, the second conductive pattern may be an additional layer of the display substrate, or may be disposed in the same layer and made of the same material as the original layer of the display substrate.

Optionally, the display electrode includes a first display electrode and a second display electrode. Preferably, the second conductive pattern is disposed in the same layer and includes the same material as the first display electrode of the display substrate. In this way, the second conductive pattern and the first display electrode of the display substrate can be simultaneously formed by the same patterning process, and there is no need to specialize in the second conductive pattern by an additional patterning process, thereby reducing the number of patterning processes for forming the display substrate and the production time and production cost of the display substrate. Optionally, the display electrode of the display substrate comprises a common electrode and a pixel electrode, and the first display electrode is selected from one of a common electrode and a pixel electrode.

Additionally, the first conductive pattern and the second conductive pattern are disposed in different layers, and the first conductive pattern and the second conductive pattern may be in direct contact or may be separated by an insulating layer. in a specific embodiment, the second conductive pattern is separated from the first conductive pattern by an insulating layer. In order to electrically connect the second conductive pattern and the first conductive pattern, the display substrate further includes a conductive connection portion connecting the second conductive pattern and the first display electrode. The conductive connection portion can be specially made by an additional patterning process, or can be made of the same material as the existing film layer of the display substrate.

Optionally, the conductive connection portion is made of the same material as the second display electrode of the display substrate, so that the conductive connection portion and the second display electrode of the display substrate can be simultaneously formed by the same patterning process. The conductive connection portion is not required to be specially formed by an additional patterning process, which can reduce the number of patterning processes for forming the display substrate, and reduce the production time and production cost of the display substrate. Optionally, the display electrode of the display substrate includes a common electrode and a pixel electrode, the second display electrode is selected from one of the common electrode and the pixel electrode, and the second display electrode may be the same as the first display electrode or may be different from the first display electrode.

In a specific embodiment, the first conductive pattern is a data line of the display substrate, such that the lateral capacitance between the data line and the common electrode or the pixel electrode is determined by the distance between the second conductive pattern and the common electrode or the pixel electrode. When the backlight emits light or does not emit light, the lateral capacitance between the data line and the common electrode or the pixel electrode does not change, so that the load on the data line is uniform with or without illumination, thereby eliminating the difference in pixel charging and improving the display effect of the display apparatus. In addition, the data line can be connected to the second conductive pattern through a plurality of connection points. In this way, the data line is connected in parallel with the second conductive pattern, which can also reduce the resistance of the data line and facilitate the transmission of electrical spirals on the data line.

The first conductive pattern is not limited to the data line of the display substrate, and may also be the source or the drain of the this film transistor on the display substrate. A semiconductor pattern is also retained under the source and drain of the thin film transistor, and the source and drain do not completely cover the semiconductor pattern. When the backlight emits light, the semiconductor pattern under the source and the drain is affected by the illumination and appears as a conductor; when the backlight does not emit light, the semiconductor pattern still exhibits semiconductor performance. If the second conductive pattern electrically connected to the source or the drain is not provided, the capacitance between the source and the common electrode or the pixel electrode is decided by the distance between the source and the common electrode or the pixel electrode when the backlight is not emitting light, and the capacitance between the drain and the common electrode or the pixel electrode is determined by the distance between the drain and the common electrode or the pixel electrode; When the backlight emits light, since the semiconductor pattern under the source and the drain is a conductor, and the distance between the semiconductor pattern and the common electrode or the pixel electrode is smaller than the distance between the source/the drain and the common electrode or the pixel electrode, therefore, the capacitance between the source and the common electrode or the pixel electrode is determined by the distance between the underlying semiconductor pattern and the common electrode or the pixel electrode, and the capacitance between the drain and the common electrode or the pixel electrode is determined by the distance between the underlying semiconductor pattern and the common or pixel electrode. Thus, in the case where the backlight emits light or does not emit light, the capacitance between the source/the drain and the common electrode or the pixel electrode changes, which affects the electrical signals on the source and the drain.

In one embodiment, a second conductive pattern electrically connected to the source or the drain is disposed on the display substrate. The orthographic projection of the semiconductor pattern under the source and the drain on the base substrate completely falls within the orthographic projection of the second conductive pattern on the base substrate, and the distance between the second conductive pattern and the common electrode or the pixel electrode is smaller than the distance between the semiconductor pattern and the common electrode or the pixel electrode. Thus, in the cases where the backlight emits light and or does not emit light, the capacitance between the source and the common electrode or the pixel electrode is always determined by the distance between the second conductive pattern electrically connected to the source and the common electrode or the pixel electrode, or the capacitance between the drain and the common electrode or the pixel electrode is always determined by the distance between the second conductive pattern electrically connected to the drain and the common electrode or the pixel electrode, which makes the electrical signals loaded on the source or the drain of the thin film transistor uniform in the cases with or without illumination. It is worth noting that in order not to affect the operational characteristics of the thin film transistor, the second conductive pattern electrically connected to the source and the second conductive pattern electrically connected to the drain are insulated.

In one embodiment, the second conductive pattern is disposed in the same layer and made of the same material as the gate line of the display substrate. In this way, the second conductive pattern and the gate line of the display substrate can be simultaneously formed by the same patterning process, and the second conductive pattern does not need to be specially made by an additional patterning process. Thus, the number of patterning processes for producing the display substrate can be reduced, and the production time and production cost of the display substrate can be reduced. It is worth noting that the second conductive pattern needs to be insulated from the gate line in order not to affect the normal display of the display substrate. In addition, since the gate line is generally made of opaque metal, when the second conductive pattern and the gate line are disposed in the same layer and made of the same material, the second conductive pattern is also made of opaque metal. If the second conductive pattern is located between the semiconductor pattern and the substrate, the second conductive pattern is also capable of blocking light emitted by the backlight, so the light of the backlight is prevented from being irradiated onto the semiconductor pattern to affect the properties of the semiconductor pattern. Accordingly, the influence of illumination on the display of the display substrate is further avoided.

Some embodiments of the present disclosure also provide a display apparatus including the display substrate as described above. The display apparatus may further include, but is not limited to, a radio frequency unit, a network module, an audio output unit, an input unit, a sensor, a display unit, a user input unit, an interface unit, a memory, a processor, and a power supply. It will be understood by those skilled in the art that the structure of the above display apparatus does not constitute a limitation of the display apparatus, and the display apparatus may include more or less components described above, or some components in combination, or different component arrangements. In one embodiment of the present disclosure, the display apparatus includes, but is not limited to, a display, a mobile phone, a tablet computer. a television, a wearable electronic apparatus, a navigation display apparatus, and the like.

The display apparatus may be any product or component having a display function, such as a liquid crystal television, a liquid crystal display, a digital photo frame, a mobile phone, a tablet computer, etc., wherein the display apparatus further includes a flexible circuit board, a printed circuit board, and a backboard.

One embodiment of the present disclosure further provides a manufacturing method of display substrate, comprising forming a semiconductor pattern and a first conductive pattern stacked on a base substrate, wherein a first orthographic projection of the first conductive pattern on the base substrate falls within a second orthographic projection of the semiconductor pattern on the base substrate, and the manufacturing method further includes:

Forming a second conductive pattern electrically connected to the first conductive pattern, a distance between the second orthographic projection and a fourth orthographic projection of the display electrode of the display substrate on the base substrate is greater than a distance between the third orthographic projection of the second conductive pattern on the base substrate and the fourth orthographic projection.

In the embodiment of the present disclosure, the display substrate includes a second conductive pattern electrically connected to the first conductive pattern, and the distance between the second orthographic projection and a fourth orthographic projection of the display electrode of the display substrate on the substrate is greater than the distance between the third orthographic projection oldie second conductive pattern on the base substrate and the fourth orthographic projection. Thus, the distance between the second conductive pattern and the display electrode is smaller than the distance between at least a portion of the semiconductor pattern and the display electrode. When the display substrate is in operation, the lateral capacitance between the first conductive pattern and the display electrode is determined by the distance between the second conductive pattern and the display electrode, rather than the distance between the semiconductor pattern and the display electrode. Since the second conductive pattern is always a conductor, the lateral capacitance between the first conductive pattern and the display electrode does not change in the cases where the backlight emits light or does not emit light. Therefore, the load on the first conductive pattern is not affected the difference in pixel charging is not generated, and the display apparatus is prevented from being poorly displayed. In addition, the first conductive pattern can be connected to the second conductive pattern through a plurality of connection points. Thus, the first conductive pattern may be connected in parallel with the second conductive pattern. Accordingly, the resistance of the first conductive pattern can also be reduced.

In one embodiment, the second orthographic projection hills within the third orthographic projection such that in the region where the semiconductor pattern is present. the orthographic projection of the semiconductor pattern on the base substrate falls into the orthographic projection of the second conductive pattern on the base substrate, and the distance between the second conductive pattern and the display electrode of the display substrate is smaller than the distance between the semiconductor pattern and the display electrode. Thus, when the display substrate is in operation, the lateral capacitance between the first conductive pattern and the display electrode is determined by the distance between the second conductive pattern and the display electrode, rather than the distance between the semiconductor pattern and the display electrode. Accordingly, the lateral capacitance between the first conductive pattern and the display electrode does not change in the cases where the backlight emits light or does not emit light. Therefore, the load on the first conductive pattern is not affected, the difference in pixel charging is not generated, and the display apparatus is prevented from being poorly displayed. The distance between the first conductive pattern and the display electrode is the distance between the two in the horizontal direction, that is, the distance between the orthographic projections of the two on the substrate. For example, the distance between the second conductive pattern and the display electrode of the display substrate is the distance between the third orthographic projection and the orthographic projection of the display electrode on the base substrate, the distance between the semiconductor pattern and the display electrode is the distance between the second orthographic projection and the graphic projection of the display electrode on the base substrate, and the distance between the orthographic projections is the shortest distance between the contours of the orthographic projections.

Wherein, the second conductive pattern may be an additional layer of the display substrate, or may be disposed in the same layer and made of the same material as the original layer of the display substrate.

Optionally, the display electrode includes a first display electrode and a second display electrode.

In a specific embodiment, forming the second conductive pattern comprises:

The second conductive pattern and the first display electrode of the display substrate can be simultaneously famed by a same patterning process, and there is no need to specialize in the second conductive pattern by an additional patterning process, thereby reducing the number of patterning processes for forming the display substrate and reducing the production time and production cost of the display substrate. Wherein, the display electrode of the display substrate comprises a common electrode and a pixel electrode, and the first display electrode is selected from one of a common electrode and a pixel electrode.

Optionally, the first conductive pattern and the second conductive pattern are. disposed in different layers, and the first conductive pattern and the second conductive pattern may be in direct contact or may be separated by an insulating layer. In a specific embodiment, the second conductive pattern is separated from the first conductive pattern by an insulating layer. In order to electrically connect the second conductive pattern and the first conductive pattern, the display substrate further includes a conductive connection portion connecting the second conductive pattern and the first conductive pattern. The conductive connection portion can be specially made by an additional patterning process, or can be made of the same material as the existing film layer of the display substrate.

Optionally, the conductive connection, portion is made of the same material as the second display electrode of the display substrate, and the manufacturing method further comprises:

Forming a conductive connection portion connecting the second conductive pattern and the first display electrode with a. second display electrode of the display substrate by one patterning process. Thus. the conductive connection portion is not required to be specially formed by an additional patterning process, which can reduce the number of patterning processes for forming the display substrate, and reduce the production time and production cost of the display substrate. The display electrode of the display substrate includes a common electrode and a pixel electrode, the second display electrode is selected from one of the common electrode and the pixel electrode, and the second display electrode may be the same as the first display electrode or may be different from the first display electrode..

In a specific embodiment, the first conductive pattern is a data line of the display substrate, such that the lateral capacitance between the data line and the common electrode or the pixel electrode is determined by the distance between the second conductive pattern and the common electrode or the pixel electrode. When the backlight emits light or does not emit light, the lateral capacitance between the data line and the common electrode or the pixel electrode does not change, so that the load on the data line is uniform under the cases with or without illumination, thereby eliminating the difference in pixel charging and improving the display effect of the display apparatus. In addition, the data line can be connected to the second conductive pattern through a plurality of connection points. In this way, the data line may be connected in parallel with the second conductive pattern, which can further reduce the resistance of the data line and facilitate the transmission of electrical. signals on the data line.

The first conductive pattern is not limited to the data line of the display substrate, and may also be the source or the drain of the thin film transistor on the display substrate. A semiconductor pattern is also retained under the source and drain of the thin film transistor, and the source and drain do not completely cover the semiconductor pattern. When the backlight emits light, the semiconductor pattern under the source and the drain is affected by the illumination and appears as a conductor; when the backlight is not illuminated, the semiconductor pattern still exhibits semiconductor performance. If the second conductive pattern electrically connected to the source or the drain is not provided, when the backlight is not emitting light, the capacitance between the source and the common electrode or the pixel electrode is decided by the distance between the source and the common electrode or the pixel electrode, and the capacitance between the drain and the common electrode or the pixel electrode is determined by the distance between the drain and the common electrode or the pixel electrode. When the backlight emits light, since the semiconductor pattern under the source and the drain is a conductor, and the distance between the semiconductor pattern and the common electrode or the pixel electrode is smaller than the distance between the source the drain and the common electrode or the pixel electrode, therefore, the capacitance between the source and the common electrode or the pixel electrode is determined by the distance between the underlying semiconductor pattern and the common electrode or the pixel electrode, and the capacitance between the drain and the common electrode or the pixel electrode is determined by the distance between the underlying semiconductor pattern and the common or pixel electrode. Thus, in the cases where the backlight emits light or does not emit light, the capacitance between the source/the drain and the common electrode or the pixel electrode changes, which affects the electrical signals on the source and the drain.

In one embodiment, a second conductive pattern electrically connected to the source or the drain is disposed on the display substrate, the orthographic projection of the semiconductor pattern under the source and the drain on the base substrate completely falls within the orthographic projection of the second conductive pattern on the base substrate, and the distance between the second conductive pattern and the common electrode or the pixel electrode is smaller than the distance between the semiconductor pattern and the common electrode or the pixel electrode. Thus, in the cases where the backlight emits light or does not emit light, the capacitance between the source and the common electrode or the pixel electrode is always determined by the distance between the second conductive pattern electrically connected to the source and the common electrode or the pixel electrode, the capacitance between the drain and the common electrode or the pixel electrode is always determined by the distance between the second conductive pattern electrically connected to the drain and the common electrode or the pixel electrode, which makes the electrical signals loaded on the source or the drain of the thin film transistor e uniform. under the cases with or without illumination. It is worth noting that in order not to affect the operational characteristics of the thin film transistor, the second conductive pattern electrically connected to the source and the second conductive pattern electrically connected to the drain are insulated.

Optionally, when the first conductive pattern is a data line of the display substrate, forming the second conductive pattern includes the following:

The second conductive pattern and the gate line of the display substrate can be simultaneously filmed by the same patterning process, and the second conductive pattern does not need to be specially made by an additional patterning process. The number of patterning processes for producing the display substrate can be reduced, and the production time and production cost of the display substrate can be reduced. It is worth noting that the second conductive pattern needs to be insulated from the gate line in order not to affect the normal display of the display substrate. In addition, since the gate line is generally made of opaque metal, when the second conductive pattern and the gate line are disposed in the same layer and made of the same material, the second conductive pattern is also made of opaque metal. If the second conductive pattern is located between the semiconductor pattern and the substrate, the second conductive pattern is also capable of blocking light emitted by the backlight, so the light of the backlight is prevented from being irradiated onto the semiconductor pattern to affect the properties of the semiconductor pattern, and the influence of illumination on the display of the display substrate is further avoided.

The technical solution of the present disclosure is further introduced in the following with reference to the accompanying drawings and specific embodiments:

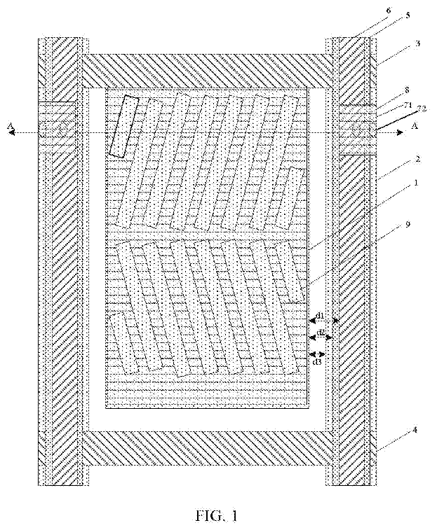

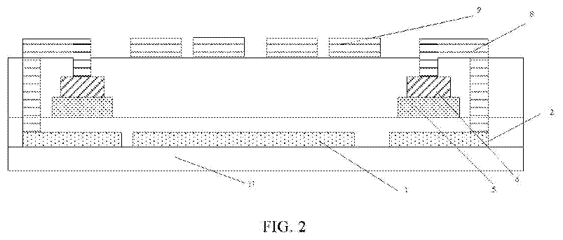

As shown in FIG. 1 and FIG. 2, in one embodiment, the display substrate includes a semiconductor pattern 5 and a first conductive pattern 6 which are stacked, wherein the first orthographic projection of the first conductive pattern 6 on the base substrate 11 is located in the second orthographic projection of the semiconductor pattern 5 on the base substrate 11. It can be seen that the distance d1 between the first conductive pattern 6 and the common electrode 1 is greater than the distance d2 between the semiconductor pattern 5 and the common electrode 1.

Optionally, the display substrate further includes a second conductive pattern 2 disposed in the same layer and made of the same material as the common electrode 1, and the second conductive pattern 2 and the first conductive pattern 6 are separated by an insulating layer. A conductive connection portion 8 is electrically connected to the first conductive pattern 6 and the second conductive pattern 2 through the via holes 71 and 72 penetrating the insulating layer, respectively. A second orthographic projection of the semiconductor pattern 5 on the base substrate 11 is located in a third orthographic projection of the second conductive pattern 2 on the base substrate II. It can be seen that the distance d2 between the semiconductor pattern 5 and the common electrode 1 is greater than the distance d3 between the second conductive pattern 2 and the common electrode 1.

Optionally, the conductive connecting portion 8 is made of the same material as the pixel electrode 9, so that the conductive connecting portion 8 and the pixel electrode 9 can be simultaneously formed by the same patterning process. It is not necessary to specially fabricate the conductive connecting, portion 8 by an additional patterning process, which can reduce the number of patterning processes for producing the display substrate, and reduce the production time and production cost of the display substrate.

When the backlight emits light, the semiconductor pattern 5 is represented as a conductor by the effect of illumination. The first conductive pattern 6 is loaded with an electrical signal, and both the semiconductor pattern 5 and the second conductive pattern 2 are electrically connected to the first conductive pattern 6, and the same electrical signal as the first conductive pattern 6 is loaded. Since the distance d2 between the semiconductor pattern 5 and the common electrode 1 is greater than the distance d3 between the second conductive pattern 2 and the common electrode 1, the distance d1 between the first conductive pattern 6 and the common electrode 1 is greater than the distance d2 between the semiconductor pattern 5 and the common electrode 1, thus, among the three conductors that loaded the same electrical signal, the distance between the second conductive pattern 2. and. the common electrode 1 is the shortest. Accordingly, the lateral capacitance between the first conductive pattern 6 and the common electrode 1 depends on the distance between the second conductive pattern 2 and the common electrode 1. When the backlight is not illuminated, the semiconductor pattern 5 is represented as a semiconductor, the first conductive pattern 6 is loaded with an electrical signal, and the second conductive pattern 2 is electrically connected to the first conductive pattern 6 to load the same electrical spiral as the first conductive pattern 6. Since the distance d1 between the first conductive pattern 6 and the common electrode 1 is greater than the distance d3 between the second conductive pattern 2 and the common electrode 1. Thus, between the two conductors loaded with the same electrical signal, the distance between the second conductive pattern 2 and the common electrode 1 is the shortest, and the lateral capacitance between the first conductive pattern 6 and the common electrode 1 depends on the distance between the second conductive pattern 2 and the common electrode 1. It can be seen that when the backlight emits light or does not emit light, the lateral capacitance between the first conductive pattern 6 and the common electrode 1 always depends on the distance between the second conductive pattern 2 and the common electrode 1, and does not change, so that in the case of the presence or absence of illumination, the second conductive pattern 2 can Always shield the electric field between the semiconductor pattern 5 and the common electrode 1 so that the load on the first conductive pattern 6 is not affected by the illumination, thereby eliminating Water Fall failure.

Optionally, as shown in FIG. 1, the distance between the two refers to the distance between the two in the horizontal direction, that is, the distance between the orthographic projections of the two on the base substrate 11. For example, d1 is the distance between the first orthographic projection and the orthographic projection of the common electrode 1 on the base substrate 11, d2 is the distance between the second orthographic projection and the orthographic projection of the common electrode 1 on the base substrate 11, and d3 is the distance between the third orthographic projection and the orthographic projection of the common electrode 1 on the base substrate 11, and the distance between the orthographic projections is the shortest distance between the contours of the orthographic projections.

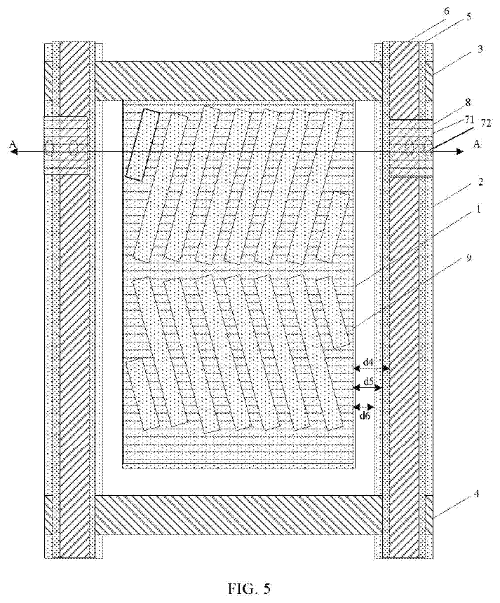

For the pixel electrode 9, as shown in FIGS. 5 and 2, the distance d4 between. the first conductive pattern 6 and the pixel electrode 9 is greater than the distance d5 between the semiconductor pattern 5 and the pixel electrode 9, the distance d5 between the semiconductor pattern 5 and the pixel electrode 9 is greater than the distance d6 between the second conductive pattern 2 and the pixel electrode 9.

When the backlight emits light, the semiconductor pattern 5 is represented as a conductor by the effect of illumination. The first conductive pattern 6 is loaded with an electrical signal, and both the semiconductor pattern 5 and the second conductive pattern 2 are electrically connected to the first conductive pattern 6, and the same electrical signal as the first conductive pattern 6 is loaded thereon. Since, the distance d5 between the semiconductor pattern 5 and the pixel electrode 9 is greater than the distance d6 between the second conductive pattern 2. and the pixel electrode 9, the distance d4 between the first conductive pattern 6 and the pixel electrode 9 is greater than the distance d5 between the semiconductor pattern 5 and the pixel electrode 9, thus, among the three conductors that are loaded with the same electrical signal, the distance between the second conductive pattern 2 and the pixel electrode 9 is the shortest, and the lateral capacitance between the first conductive pattern 6 and the pixel electrode 9 depends on the distance between the second conductive pattern 2 and the pixel electrode 9. When the backlight is not illuminated, the semiconductor pattern 5 is represented as a semiconductor, the first conductive pattern 6 is loaded with an electrical signal, and the second conductive pattern 2 is electrically connected to the first conductive pattern 6 to load the same electrical signal as the first conductive pattern 6. Since the distance d4 between the first conductive pattern 6 and the pixel electrode 9 is greater than the distance d6 between the second conductive pattern 2 and the pixel electrode 1, thus, between the two conductors that load the same electrical signal, the distance between the second conductive pattern 2 and the pixel electrode 9 is the shortest, and the lateral capacitance between the first conductive pattern 6 and the pixel electrode 9 depends on the distance between the second conductive pattern 2 and the pixel electrode 9. It can be seen that when the backlight emits light or does not emit light, the lateral capacitance between the first conductive pattern 6 and the pixel electrode 9 always depends on the distance between the second conductive pattern 2 and the pixel electrode 9, and does not change, so that in the cases of the presence or absence of illumination, the second conductive pattern 2 can always shield the electric field between the semiconductor pattern 5 and the pixel electrode 9 so that the load on the first conductive pattern 6 is not affected by the illumination, thereby eliminating Water Fall failure.

Wherein, as shown in FIG. 5, the distance between the two refers to the distance between the two in the horizontal direction, that is, the distance between the orthographic projections of the two on the base substrate 11. For example, d4 is the distance between the first orthographic projection and the orthographic projection of the pixel electrode 9 on the base substrate 11, d5 is the distance between the second orthographic projection and the orthographic projection of, the pixel electrode 9 on the base substrate 11, and d6 is the distance between the third orthographic projection and the orthographic projection of the pixel electrode 9 on the base substrate 11, and the distance between the orthographic projections is the shortest distance between the contours of the orthographic projections.

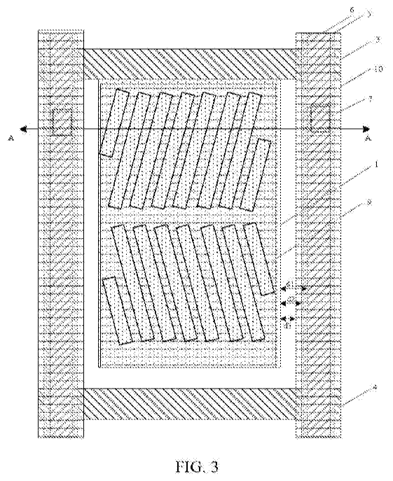

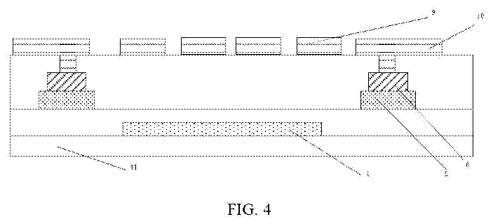

As shown in FIG. 3 and FIG. 4, in one embodiment, the display substrate includes a semiconductor pattern 5 and a first conductive pattern 6 which are stacked, wherein the first orthographic projection of the first conductive pattern 6 on the base substrate 11 is located in the second orthographic. projection of the semiconductor pattern 5 on the base substrate 11, and the distance d1 between the first conductive pattern 6 and the common electrode 1 is greater than the distance d2 between the semiconductor pattern 5 and the common electrode 1.

Optionally, the display substrate further includes a second conductive pattern 10 disposed in the same layer and made of same material as the pixel electrode 9, and the second conductive pattern 10 and the first conductive pattern 6 are separated by an insulating layer. The second conductive pattern 10 is electrically connected to the tint conductive, pattern 6 through the via hole 7 penetrating the insulating layer. A second orthographic projection of the semiconductor pattern 5 on the base substrate 11 is located in a third orthographic projection of the second conductive pattern 10 on the base substrate 11. The distance d2 between the semiconductor pattern 5 and the common electrode 1 is greater than the distance d3 between the second conductive pattern 10 and the common electrode 1.

When the backlight emits light, the semiconductor pattern 5 is represented as a conductor by the effect of illumination. The first conductive pattern 6 is loaded with an electrical signal, and both the semiconductor pattern 5 and the second conductive pattern 10 are electrically connected to the first conductive pattern 6, and the same electrical signal as the first conductive pattern 6 is loaded thereon. Since the distance d2 between the semiconductor pattern 5 and the common electrode 1 is greater than the distance d3 between the second conductive pattern 10 and the common electrode 1, the distance d1 between the first conductive pattern 6 and the common electrode 1 is greater than the distance d2 between the semiconductor pattern 5 and the common electrode 1, thus, among the three conductors that load the same electrical signal, the distance between the second conductive pattern 10 and the common electrode 1 is the shortest. Thus, the lateral capacitance between the first conductive pattern 6 and the common electrode 1 depends on the distance between the second conductive pattern 10 and the common electrode 1. When the backlight is not illuminated, the semiconductor pattern 5 is represented as a semiconductor, the first conductive pattern 6 is loaded with an electrical signal, and the second conductive pattern 10 is electrically connected to the first conductive pattern 6 to load the same electrical signal as the first conductive pattern 6. Since the distance d1 between the first conductive pattern 6 and the common electrode 1 is greater than the distance d3 between the second conductive pattern 10 and the common electrode 1, thus, between the two conductors that load the same electrical signal, the distance between the second conductive pattern 10 and the common electrode 1 is the shortest. Thus, the lateral capacitance between the first conductive pattern 6 and the common electrode 1 depends on the distance between the second conductive pattern 10 and the common electrode 1. It can be seen that when the backlight emits light or does not emit light, the lateral capacitance between the first conductive pattern 6 and the common electrode 1 always depends on the distance between the second conductive pattern 10 and the common electrode 1, and does not change, so that in the cases of the presence or absence of illumination, the second conductive pattern 10 can always shield the electric field between the semiconductor pattern 5 and the common electrode 1 so that the load on the first conductive pattern 6 is not affected by the illumination, thereby eliminating Water Fall failure.

Wherein, as shown in FIG. 3, the distance between the two refers to the distance between the two in the horizontal direction, that is, the distance between the orthographic projections of the two on the base substrate 11. For example, d1 is the distance between the first orthographic projection and the orthographic projection of the common electrode 1 on the base substrate 11, d2 is the distance between the second orthographic projection and the orthographic. projection of the common electrode 1 on the base substrate 11, and d3 is the distance between the third orthographic projection and the orthographic projection of the common electrode 1 on the base substrate 11, and the distance between the orthographic projections is the shortest distance between the contours of the orthographic projections.

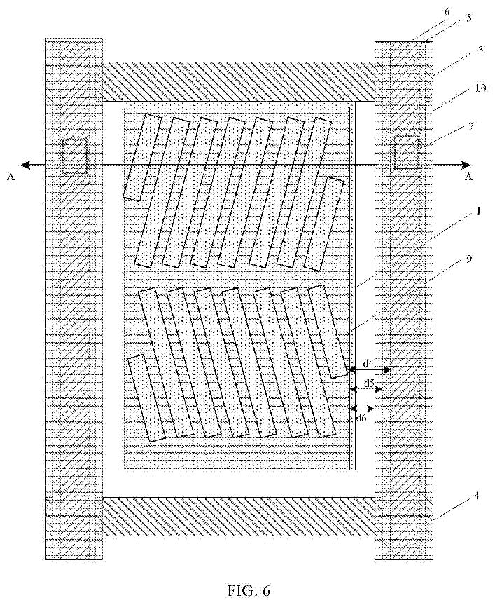

As shown in FIGS. 6 and 4, in one embodiment, the distance d4 between the first conductive pattern 6 and the pixel electrode 9 is greater than the distance d5 between the semiconductor pattern 5 and the pixel electrode 9, and the distance d5 between the semiconductor pattern 5 and the pixel electrode 9 is greater than the distance d6 between the second conductive pattern 2 and the pixel electrode 9.

When the backlight emits light, the semiconductor pattern 5 is represented as a. conductor by the effect of illumination. The first conductive pattern 6 is loaded with an electrical signal, and both the semiconductor pattern 5 and the second conductive pattern 10 are electrically connected to the first conductive pattern 6, and the same electrical signal as the first conductive pattern 6 is loaded thereon. Since the distance d5 between the semiconductor pattern 5 and the pixel electrode 9 is greater than the distance d6 between the. second conductive pattern 10 and the pixel electrode 9, the distance d4 between the first conductive pattern 6 and the pixel electrode 9 is greater than the distance d5 between the semiconductor pattern 5 and the pixel electrode 9, thus, among the three conductors that loaded with the same electrical signal, the distance between the second conductive pattern 10 and the pixel electrode 9 is the shortest. Thus, the lateral capacitance between the first conductive pattern 6 and the pixel electrode 9 depends on the distance between the second conductive pattern 10 and the pixel electrode 9. When the backlight is not illuminated, the semiconductor pattern 5 is represented as a semiconductor, the first conductive pattern 6 is loaded with an electrical spiral, and the second conductive pattern 10 is electrically connected to the first conductive pattern 6 to load the same electrical signal as the first conductive pattern 6. Since the distance d4 between the first conductive pattern 6 and the pixel electrode 9 is greater than the distance do between the second conductive pattern 10 and the pixel electrode 1, thus, between the two conductors that load the same electrical signal, the distance between the second conductive pattern 10 and the pixel electrode 9 is the shortest. Thus, the lateral capacitance between the first conductive pattern 6 and the pixel electrode 9 depends on the distance between the second conductive pattern 10 and the pixel electrode 9. It can be seen that when the backlight emits light or does not emit light, the lateral capacitance between the first conductive pattern 6 and the pixel electrode 9 always depends on the distance between the second conductive pattern 10 and the pixel electrode 9, and does not change, so that in the cases of the presence or absence of illumination, the second conductive pattern 10 can always shield the electric field between the semiconductor pattern 5 and the pixel electrode 9 so that the load on the first conductive pattern 6 is not affected by the illumination, thereby eliminating Water Fall failure.

Wherein, as shown in FIG. 6, the distance between the two refers to the distance between the two in the horizontal direction, that is, the distance between the orthographic projections of the two on the base substrate 11. For example, d4 is the distance between the first orthographic projection and the orthographic projection of the pixel electrode 9 on the base substrate 11, d5 is the distance between the second orthographic projection and the orthographic projection of the pixel electrode 9 on the base substrate 11, and d6 is the distance between the third. orthographic projection and the orthographic projection. f the pixel electrode 9 on the base substrate 11, and the distance between the orthographic projections is the shortest distance between the contours of the orthographic projections.

In the above embodiment, the second conductive pattern 2 may also be disposed in the same layer and made of the same material as the common electrode line 3 or the gate line 4, but at this time, the second conductive pattern 2 needs to be simulated from the common electrode line 3 or the gate line 4.

It should be noted that the various embodiments in the present specification are described in a progressive manner, and the same or similar parts between the various embodiments may be referred to each other, and each embodiment focuses on differences from other embodiments. In particular, for the method embodiment, since it is basically similar to the product embodiment, the description is relatively simple, and the relevant parts can be referred to the description of the product embodiment.

Unless otherwise defined, technical terms or scientific terms used in the present disclosure are intended to be understood in the ordinary meaning of the ordinary skill l of the art. The words “first,” “second,” and similar terms used in the present disclosure do not denote any order, quantity, or importance, but are used to distinguish different components. The word “comprising” or “including” or the like means that the element or item preceding the word cover the elements or objects and their equivalents listed after the word, and the other elements or objects are not excluded. The words “connected” or “coupled” and the like are not limited to physical or mechanical connections, but may include electrical, connections, whether direct or indirect, “Upper”, “lower”, “left”, “right”, etc. are only used to indicate the relative positional relationship, and when the absolute position of the object to be described is changed, the relative positional relationship may also change accordingly

It will be understood that when an element such as a layer, a film, a region or a substrate is referred to as being “on” or “under” another element, the element may be “directly” “on” or “under” another element, or an intermediate element may be present.

In the description of the above embodiments, specific features, structures, materials or characteristics may be combined in any suitable .manner in any one or more embodiments or examples.

The above description is only a specific embodiment of the present disclosure, but the scope of protection of the present disclosure is not limited thereto. Any changes or substitutions that are obvious to those skilled in the art within the scope of the present disclosure are intended to be included within the scope of the present disclosure. Therefore, the scope of protection of the present disclosure should be determined by the scope of the claims.

1. A display substrate, comprising:
a semiconductor pattern and a first conductive pattern stacked on a base substrate, and
a second conductive pattern electrically connected to the first conductive pattern,
wherein a first orthographic projection of the first conductive pattern on the base substrate falls within a second orthographic projection of the semiconductor pattern on the base substrate, and
a distance between the second orthographic projection and a fourth orthographic projection of a display electrode of the display substrate on the base substrate is greater than a. distance between a third orthographic projection of the second conductive pattern on the base substrate and the fourth orthographic projection.

2. The display substrate according to claim 1, wherein the second orthographic projection falls within the third orthographic projection.

3. The display substrate according to claim 1, wherein the first conductive pattern is connected in parallel with the second conductive pattern.

4. The display substrate according to claim 1, wherein the display electrode comprises a first display electrode and a second display electrode, and the second. conductive pattern is disposed in a same layer and made of a same material as the first display electrode of the display substrate.

5. The display substrate according to claim 4, wherein the second conductive pattern is separated from the first conductive pattern by an insulating layer, the display substrate further comprises a conductive connection portion connecting the second conductive pattern and the first conductive pattern, and the conductive connection portion is made of a same material as the second display electrode of the display substrate.

6. The display substrate according to claim 4, wherein the first display electrode is one of a common electrode or a pixel electrode, and the second display electrode is the other one of the common electrode or the pixel electrode.

7. The display substrate according o claim 1, wherein the first conductive pattern is a data line of the display substrate.

8. The display substrate according to claim 7, wherein the second conductive pattern is disposed in a same layer and made of a same material as a gate line of the display substrate and is insulated from the gate line.

9. The display substrate according to claim 8, wherein the second conductive pattern is between the semiconductor pattern and the base substrate, and the second conductive pattern is made of an opaque metal.

10. The display substrate according to claim 1, wherein the first conductive pattern is a source or a drain of a thin film transistor on the display substrate.

11. The display substrate according to claim 10, wherein the semiconductor pattern is under the source or the drain of the thin film transistor, and the source or the drain do not completely cover the semiconductor pattern.

12. A display apparatus comprising the display substrate according to claim 1.

13. A manufacturing method of a display substrate, comprising:
forming a semiconductor pattern and a first conductive pattern stacked on a base substrate, and
forming a second conductive pattern electrically connected to the first conductive pattern.
wherein a first orthographic projection of the first conductive pattern on the base substrate falls within a second orthographic projection of the semiconductor pattern on the base substrate, a distance between the second orthographic projection and a fourth orthographic projection of a display electrode of the display substrate on the base substrate is greater than a distance between a third orthographic projection of the second conductive pattern on the base substrate and the fourth orthographic projection.

14. The manufacturing method of the display substrate according to claim 13, wherein the first conductive pattern is connected in parallel with the second conductive pattern.

15. The manufacturing method of the display substrate according to claim 13, wherein the display electrode comprises a first display electrode and a second display electrode, and forming the second conductive pattern comprising:
forming the second conductive pattern and the first display electrode of the display substrate by one patterning process.

16. The manufacturing method of the display substrate according to claim 14, wherein the second conductive pattern and the first conductive pattern are separated by an insulating layer, and the manufacturing method further comprising:
forming a conductive connection portion connecting the second conductive pattern with the first conductive pattern and the second display electrode of the display substrate by one patterning process.

17. The manufacturing method of the display substrate according to claim 15, wherein the first display electrode is one of a common electrode or a pixel electrode, and the second display electrode is the other one of the common electrode or the pixel electrode.

18. The manufacturing method of the display substrate according to claim 13, wherein the first conductive pattern is a data line of the display substrate, and forming the second conductive pattern comprising:
forming the second conductive pattern and a gate line of the display substrate by one patterning process.

19. The manufacturing method of the display substrate according to claim 18, wherein the second conductive pattern is between the semiconductor pattern and the base substrate, and the second conductive pattern is made of an opaque metal.

20. The manufacturing method of the display substrate according to claim 13, wherein the first conductive pattern is a source or a drain of a thin film transistor on the display substrate
